(19) United States
(12) Patent Application Publication
(10) Pub. No.: US 2026/0319669 A1
(43) Pub. Date: Oct. 15, 2026

(54) MEMORY SYSTEM, DATA PROCESSING SYSTEM, AND METHOD OF OPERATING THE DATA PROCESSING SYSTEM

(71) Applicant: SK hynix Inc., Gyeonggi-do (KR)

(72) Inventors: Geon Woo KIM, Gyeonggi-do (KR); Byung Cheol YU, Gyeonggi-do (KR); Jeung Hun JEUNG, Gyeonggi-do (KR)

(21) Appl. No.: 19/315,680

(22) Filed: Sep. 1, 2025

(30) Foreign Application Priority Data
Apr. 14, 2025 (KR) 10-2025-0048058

(51) Int. Cl. G06F 3/06; G11C 29/10

(52) U.S. Cl. CPC G06F 3/0617; G06F 3/0653; G06F 3/0673; G11C 29/10

(57) ABSTRACT

A memory system including a memory comprising a plurality of memory blocks; and a memory controller is provided. The memory controller may be configured to perform a time check at regular intervals when a first command among commands transmitted from a host is input, scan a command table of commands that are not completed among the commands, scan a command table of commands that are not completed among the commands, generate first snapshot data, and scan a command table of commands that are not completed among the commands, generate second snapshot data, and enter a state in which the command cannot be processed.

The present application claims priority to Korean Patent Application No. 10-2025-0048058, filed on Apr. 14, 2025, the disclosure of which is incorporated herein by reference in its entirety.

### TECHNICAL FIELD

Embodiments of the present disclosure relate to a memory system, a data processing system, and a method of operating the data processing system.

### Background of the Disclosure

A memory system is a system configured to store data based on requests from a host (e.g., an external device), such as a computer, a mobile terminal such as a smartphone or tablet, or various electronic devices.

The memory system may include a memory and a memory controller for controlling the memory. The memory controller may receive a command from a host and execute or control operations for reading data from the memory, writing/programming data to the memory, or erasing data from the memory based on the received command.

### SUMMARY

Accordingly, some embodiments of the present disclosure can solve many disadvantages of the prior art, and provide a memory system that may detect whether a command has been completed internally in the memory system itself, leave snapshot data on the internal state of the data system, and then enter an operation or panic state of the data system, thereby preventing the occurrence of reset hangs and blue screens and enabling failure analysis of the data system later using telemetry including snapshot data.

Some embodiments of the present disclosure can provide a data processing system that may detect whether a command has been completed internally in the memory system itself, leave snapshot data on the internal state of the data system, and then enter the operation or panic state of the data system, thereby preventing the occurrence of reset hangs and blue screens and enabling failure analysis of the data system later using telemetry including snapshot data.

Some embodiments of the present disclosure can provide a method of operating the data processing system that may detect whether a command has been completed internally in the memory system itself, leave snapshot data on the internal state of the data system, and then enter the operation or panic state of the data system, thereby preventing the occurrence of reset hang and blue screen and enabling failure analysis of the data system later using telemetry including snapshot data.

The embodiments of the present disclosure are not limited to those mentioned above, and other technical features and objects can be inferred from the present disclosure.

Based on an embodiment, a memory system may include a memory comprising a plurality of memory blocks; and a memory controller. The memory controller may be configured to perform a time check at regular intervals when a first command among commands transmitted from a host is input, scan a command table of commands that are not completed among the commands when the time point of the time check is before a first threshold time, scan a command table of commands that are not completed among the commands, generate first snapshot data, when the time check time is between the first threshold time and a second threshold time, and scan a command table of commands that are not completed among the commands, generate second snapshot data, and enter a state in which the command cannot be processed, when the time check time is after the second threshold time. The first snapshot data or the second snapshot data may be configured as telemetry log data and transmitted to the host.

Based on an embodiment, a data processing system may include a host, and a memory system including a memory comprising a plurality of memory blocks and a memory controller. The memory controller may be configured to generate snapshot data within the memory system by itself, convert the snapshot data into telemetry log data, and transmit it to the host upon request of the memory controller itself or the host.

Based on an embodiment, a method of operating a data processing system may include operating a memory system; determining whether commands are input from a host; and performing a time check at regular intervals when a first command among commands transmitted from a host is input. A time check may be performed at regular intervals when a first command among commands transmitted from a host is input, when the time point of the time check is before a first threshold time, a command table of commands that are not completed among the commands may be scanned, when the time check time is between the first threshold time and a second threshold time, a command table of commands that are not completed among the commands may be scanned and snapshot data may be generated, and when the time check time is after the second threshold time, a command table of commands that are not completed among the commands is scanned, second snapshot data may be generated, and a state in which the command cannot be processed may be entered. The first snapshot data or the second snapshot data may be configured as telemetry log data and transmitted to the host.

Further, the scope of applicability of the present disclosure will become apparent from the detailed description given hereinafter.

Based on the embodiments, the memory system may detect whether a command has been completed internally in the memory system itself, leave snapshot data on the internal state of the data system, and then enter an operation or panic state of the data system, thereby preventing the occurrence of reset hangs and blue screens and enabling failure analysis of the data system later using telemetry including snapshot data.

However, it should be understood that the detailed description and specific embodiments are given by illustration only, since various changes and modifications within the spirit and scope of the present disclosure will become apparent to those skilled in the art from this detailed description.

### BRIEF DESCRIPTION OF THE DRAWINGS

FIG. 1 is a schematic view of a data processing system based on an embodiment of the present disclosure;

FIG. 2 is a view showing signals exchanged between a memory interface and a memory shown in FIG. 1;

FIG. 3 is a view showing the configurations of a processor shown in FIG. 1;

FIG. 4 is a view showing the configurations of a meta memory shown in FIG. 1;

FIG. 5 is a flow chart showing a method of operating a data processing system based on an embodiment of the present disclosure;

FIG. 6 is a view to showing S20 and S40 of FIG. 5;

FIG. 7 is a view showing a command table based on an embodiment of the present disclosure;

FIG. 8 is a flow chart to describe operations a data processing system based on an embodiment of the present disclosure;

FIG. 9 is a view showing the relationship between a command complete controller and a command data controller shown in FIG. 3;

FIG. 10 is a view to describe S60 and S70 of FIG. 5;

FIG. 11 is a view showing a command table at each time check point;

FIG. 12 is a view to describe S80 and S90 of FIG. 5;

FIG. 13 is a view to describe S100 and S110 of FIG. 5;

FIG. 14 is a flow chart to describe operations of a data processing system based on an embodiment of the present disclosure;

FIG. 15 is a view to describe S130 of FIG. 14;

FIG. 16 is a view to describe S140 of FIG. 14; and

FIG. 17 is a view to describe S170 of FIG. 17.

### DETAILED DESCRIPTION

Description will now be given in detail based on the embodiments disclosed herein, with reference to the accompanying drawings.

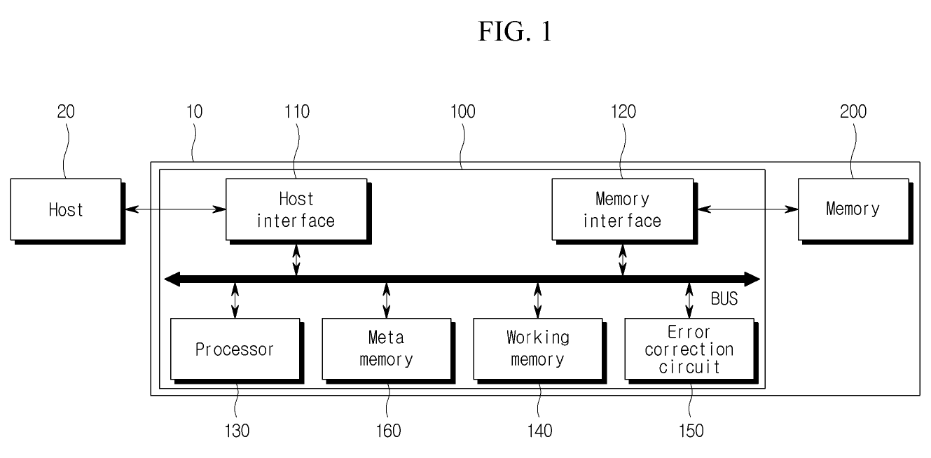

FIG. 1 is a schematic view of a data processing system based on an embodiment of the present disclosure.

Referring to FIG. 1, the data processing system based on an embodiment may include a host 20 and a memory system 10. The memory system 10 may include a memory 200 configured to store data and a memory controller 100 configured to control the memory 200.

The memory 200 may include a plurality of memory blocks and may be configured to operate in response to the control of the memory controller 100. Here, the operation of the memory 200 may include, for example, a read operation, a program operation (also called a “write operation”), and an erase operation.

For example, the memory 200 may be various types of nonvolatile memory, such as NAND Flash Memory, 3D NAND Flash Memory, NOR Flash Memory, Resistive Random Access Memory (RRAM), Phase-Change Memory (PRAM), Magnetoresistive Random Access Memory (MRAM), Ferroelectric Random Access Memory (FRAM), or Spin Transfer Torque Random Access Memory (STT-RAM).

The memory 200 may be configured to receive commands and addresses, and the like from the memory controller 100, and may access an area selected by the address among the memory cell arrays. That is, the memory 200 may perform an operation indicated by the command for an area selected by the address.

For example, the memory 200 may perform a program operation, a read operation, and an erase operation. During the program operation, the memory 200 may program data in an area selected by an address. During the read operation, the memory 200 may read data from an area selected by an address. During the erase operation, the memory 200 may erase data stored in an area selected by an address.

The memory controller 100 may control program (write), read, erase, and background operations for the memory 200. Here, the background operations can include one or more of Garbage Collection (GC), Wear Leveling (WL), Read Reclaim (RR), and Bad Block Management (BBM) operations.

The memory controller 100 may control the operation of the memory 200 based on a request from a host 20 located outside the memory system 10.

The host 20 may be one of the known devices in the art that may be connected to the memory system 10.

The host may include at least one operating system (OS). The operating system may manage and control the functions and operations of the host as a whole, and provide interaction between the host and the memory system 10.

The memory controller 100 may include a host interface 110, a memory interface 120, a processor 130, a working memory 140, an error correction circuit 150, and a meta memory 160.

The host interface 110 may be configured to provide an interface for communication with the host. For example, the host interface 110 may provide an interface that uses at least one of various communication interfaces or standards, such as a USB (Universal Serial Bus) protocol, an MMC (multimedia card) protocol, a PCI (peripheral component interconnection) protocol, a PCI-E (PCI-express) protocol, an ATA (Advanced Technology Attachment) protocol, a Serial-ATA protocol, a Parallel-ATA protocol, a SCSI (small computer small interface) protocol, an ESDI (enhanced small disk interface) protocol, an IDE (Integrated Drive Electronics) protocol, an SMBus (system management bus) protocol, an I2C (inter-integrated circuit) protocol, an I3C (improved inter-integrated circuit) protocol, a proprietary protocol, etc.

The memory interface 120 may be connected to the memory 200 and provide an interface for communication with the memory 200. That is, the memory interface 120 may be configured to provide an interface between the memory 200 and the memory controller 100 in response to the control of the control circuit 123.

The processor 130 may control the operation of the memory 200 by performing the overall control operation of the memory controller 100. The processor 130 may control the overall operation of the memory controller 100. The processor 130 may communicate with the host through the host interface 110 and communicate with the memory 200 through the memory interface 120.

The processor 130 may perform the function of a flash translation layer FTL. The processor 130 may convert a logical block address provided by a host into a physical block address through the flash translation layer FTL. The flash translation layer may receive a logical block address using a mapping table and convert it into a physical block address.

The processor 130 may control the operation of the memory controller 100 by executing firmware. The processor 130 may control the overall operation of the memory controller 100 and execute (or drive) the firmware stored in the working memory 140 at booting. The operation of the memory system 10 described in the following embodiments may be implemented in a manner in which the processor 130 executes the firmware in which the corresponding operation is defined.

Firmware is a program that runs within the memory system 10 to drive the memory system 10 and may include various functional layers. For example, the firmware may include binary data in which code for executing each of the aforementioned functional layers is defined.

For example, the firmware may include a flash translation layer that performs a conversion function between a logical block address transmitted from a host to a memory system 10 and a physical block address of the memory 200, a host interface layer HIL that interprets a command received from the host through the host interface 110 and transmits it to the flash translation layer, and a flash interface layer FIL that transmits a command instructed by the flash translation layer to the memory 200.

The processor 130 may perform a logical operation defined in firmware loaded in the working memory 140 to control the overall operation of the memory controller 100. The processor 130 may store the result of performing the logical operation defined in the firmware in the working memory 140.

The processor 130 may load the meta data (or data) required to drive the firmware from the meta memory 160.

The working memory 140 may store firmware, program code, commands or data required to drive the memory controller 100. The working memory 140 may include, for example, one or more of SRAM (Static RAM), DRAM (Dynamic RAM) and SDRAM (Synchronous DRAM) as volatile memory.

The error correction circuit 150 may detect error bits of target data using an error correction code and correct the detected error bits. Here, the target data may be, for example, data stored in the working memory 140 or data read from the memory 200.

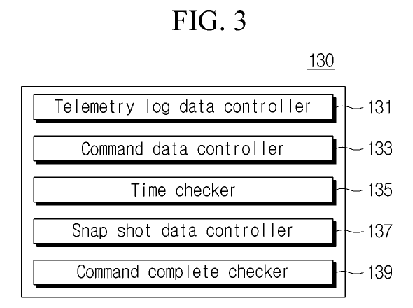

The meta memory 160 may store firmware, program code, commands or data required to drive the memory controller 100. In some embodiments, the meta memory 160 may not be configured within the memory controller 100, but may be configured within the memory 200. The meta memory 160 will be described in detail in FIG. 3.

Based on an embodiment, the telemetry log data may be data related to events that require logging of operating information of the processor 130, such as boot completion, SPL occurrence, error occurrence, receiving a command from the host, occurrence of an input/output error, starting and ending a reset, occurrence of a problem related to the working memory 140, occurrence of a problem related to the memory 200, such as erase/program/read failure, threshold voltage distribution characteristics, memory degradation characteristics, defect map, and the like, that are determined to be helpful for later debugging. The telemetry log data may include data related to all events necessary for debugging in addition to the events mentioned above.

In particular, telemetry log data may include log information of internal devices, which can be important indicators for identifying the occurrence and scenario of the problem during later debugging.

In addition, the processor 130 may store telemetry log data and transmit all or part of the telemetry log data to the host when requested by the host or periodically.

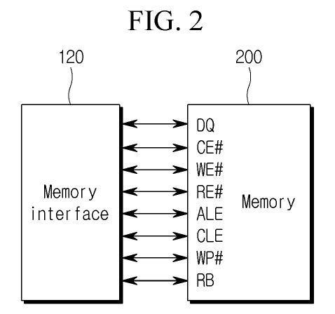

FIG. 2 is a view showing signals exchanged between a memory interface and a memory shown in FIG. 1.

Referring to FIG. 2, the memory interface 120 and the memory 200 may exchange commands, data, and/or addresses with each other through the input/output pad (DQ). For example, the input/output pad (DQ) can be composed of 8 lines so as to be able to transmit and receive 8 bits of data, and each line may transmit and receive 1 bit of data.

The memory 200 may receive a chip enable signal through the CE# pad, a write enable signal through the WE# pad, a read enable signal through the RE# pad, an address latch enable signal through the ALE pad, a command latch enable signal through the CLE pad, and a write protection signal through the WP# pad.

The memory 200 may output a ready-busy signal to the memory interface 120 through the RB pad (RB). The ready-busy signal may indicate whether the memory array of the memory 200 is in a busy state or an idle state.

In FIG. 2, the connection relationship between one memory 200 and the memory interface 120 is illustrated, but the input/output pad (DQ), the CE# pad, the WE# pad, the RE# pad, the ALE pad, the CLE pad, and the WP# pad form one channel, and the memory interface 120 and one of the memory groups may be connected through the formed channel.

FIG. 3 is a view showing the configurations of a processor shown in FIG. 1.

Based on an embodiment, the memory controller 100 may perform a time check multiple times at a predetermined interval when a first command among commands transmitted from a host is input, and when the time check is before a first threshold time point, scan a command table of process-uncompleted commands among the commands, and when the time check is between the first threshold time point and the second threshold time point, scan a command table of process-uncompleted commands among the commands, and generate first snapshot data.

Moreover, when the time check point is after the second threshold time point, the command table of unfinished commands among the commands is scanned, second snapshot data may be generated, and a state in which the command cannot be processed may be entered, and the first snapshot data or the second snapshot data may be configured as telemetry log data and may be transmitted to the host.

The memory controller 100 based on an embodiment may generate snapshot data within the memory system by itself, and convert the snapshot data into telemetry log data and transmit it to the host at the request of the memory controller itself or the host.

Hereinafter, the configuration and operation of the memory controller 100 will be described in detail with reference to FIG. 3.

Referring to FIG. 3, a processor 130 based on an embodiment may include a telemetry log data controller 131, a command data controller 133, a time checker 135, a snapshot data controller 137, and a command complete controller 139.

The telemetry log data controller 131 may generate telemetry log data at the request of the host or by the memory controller itself. The telemetry log data based on an embodiment may include snapshot data. The snapshot data can include first snapshot data and second snapshot data. This will be described later.

The command data controller 133 may generate a command table and update the generated command table.

The time checker (135) can control the command data controller (133) to scan the generated command table at each predetermined time check point.

The snapshot data controller 137 may generate snapshot data.

The command complete controller 139 may check whether processing a command requested by the host has been completed.

A detailed description of the above-described telemetry log data controller 131, command data controller 133, time checker 135, snapshot data controller 137, and command complete controller 139 will be described later.

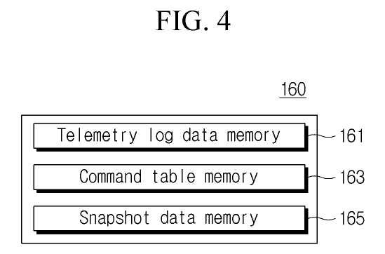

FIG. 4 is a view showing the configurations of a meta memory shown in FIG. 1.

Referring to FIG. 4, the meta memory 160 based on an embodiment may include a telemetry log data memory 161, a command table memory 163, and a snapshot data memory 165.

The telemetry log data memory 161 may store the generated telemetry log data.

The command table memory 163 may store the generated command table.

The snapshot data memory 165 may store the generated snapshot data.

A detailed description of the telemetry log data memory 161, command table memory 163, and snapshot data memory 165 described above will be described later.

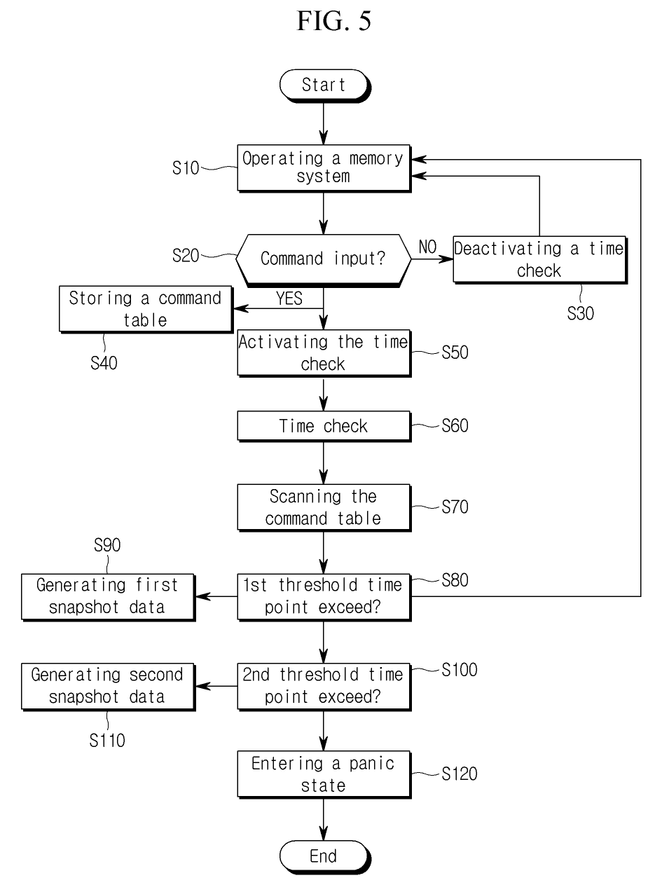

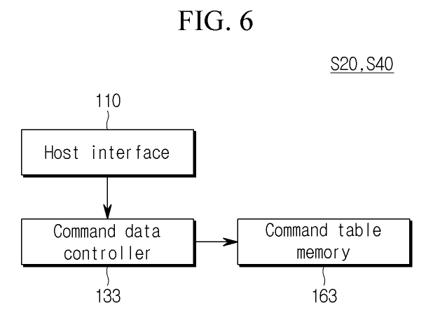

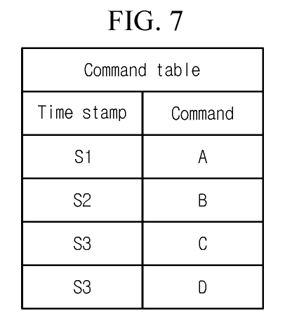

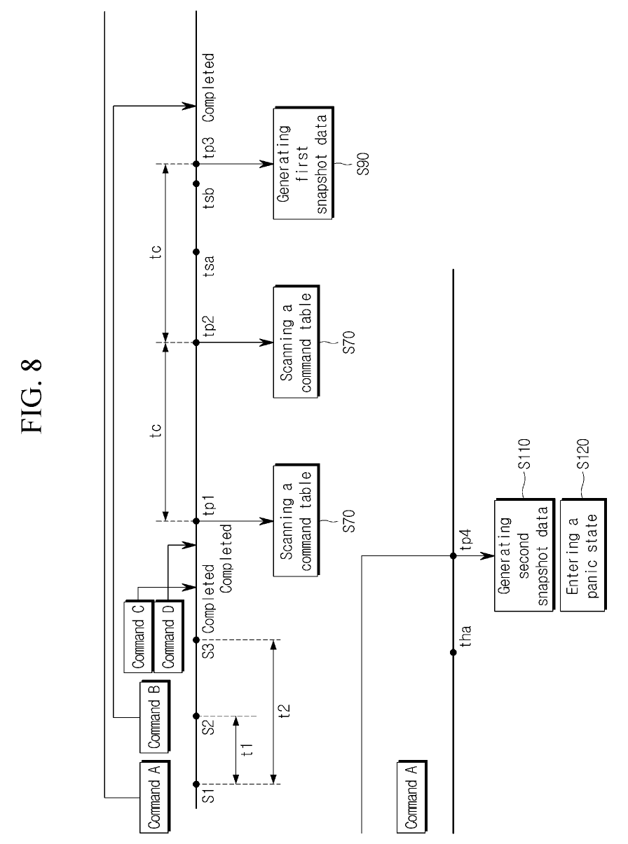

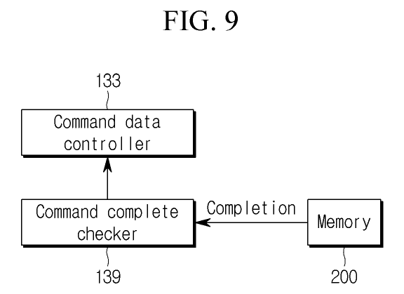

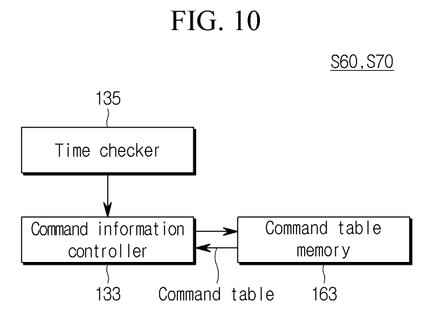

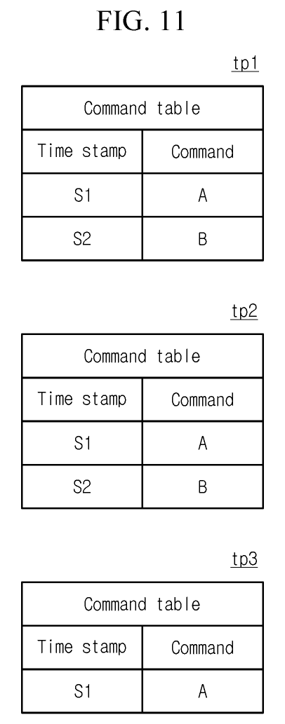

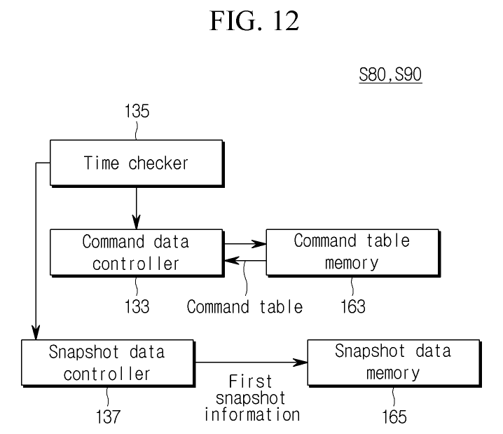

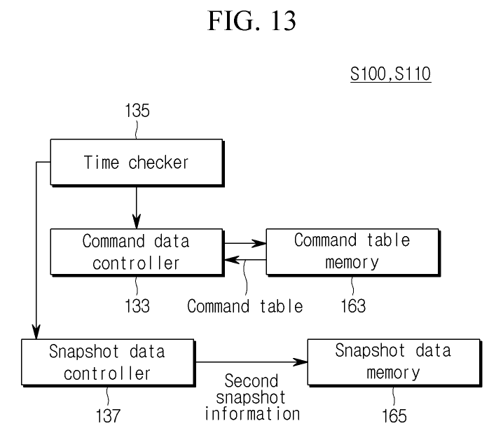

FIG. 5 is a flow chart showing a method of operating a data processing system based on an embodiment of the present disclosure. FIG. 6 is a view to showing S20 and S40 of FIG. 5. FIG. 7 is a view showing a command table based on an embodiment of the present disclosure. FIG. 8 is a flow chart to describe operations steps of a data processing system based on an embodiment of the present disclosure. FIG. 9 is a view showing the relationship between a command complete controller and a command data controller shown in FIG. 3. FIG. 10 is a view to describe S60 and S70 of FIG. 5. FIG. 11 is a view showing a command table at each time check point. FIG. 12 is a view to describe S80 and S90 of FIG. 5.FIG. 13 is a view to describe S100 and S110 of FIG. 5.

A method of operating a data processing system based on an embodiment of the present disclosure may include operating a memory system; determining whether commands have been input from a host; and performing a time check at predetermined intervals when a first command among the commands is input.

Moreover, when the time check is before the first threshold time point, the command table of the process-uncompleted command among the commands is scanned, when the time check is between the first threshold time point and the second threshold time point, the command table of the process-uncompleted command among the commands is scanned, the first snapshot data is generated. When the time check is after the second threshold time point, the command table of the process-uncompleted commands among the commands is scanned, the second snapshot data is generated, and a state in which the command cannot be processed is entered. In this disclosure, the first snapshot data or the second snapshot data may be composed of telemetry log data and may be transmitted to the host.

Hereinafter, referring to FIGS. 5-13, the method of operating the data processing system will be described in detail.

Referring to FIG. 5, the method of operating the data processing system based on one embodiment may include the operation S10 of operating the memory system.

Next, the method of operating the processing system may include the operation S20 of determining whether the command has been input. The command may be a command transmitted to the memory system 10 from the host 20. The command may include a read command, a program command, or an erase command, but the embodiments are not limited thereto, and may include various commands of the present technical field that the host 20 requests from the memory system 10. The determination of whether the command is input may be performed by the command data controller 133 of FIG. 3. That is, when the command transmitted from the host 20 through the host interface 110 is received, the host interface 110 may transmit information that the command has been input to the command data controller 133.

The method of operating the data processing system based on an embodiment may include the operation S20 of determining whether the command is input, and then the operation S30 of disabling the time check if the command is not input (NO). Based on the operation method of the data processing system based on an embodiment, when the command is not input, the time check by the time checker 135 is deactivated, so there is an advantage in that power consumption due to the time check can be significantly reduced.

The method of operating the data processing system based on an embodiment of FIGS. 5 and 6 includes after the operation S20 of determining whether the command is input, an operation S50 of activating a time check when the command is input (YES). In the present disclosure, a plurality of commands are input, and the memory controller 100 may group the plurality of commands input in succession into one group and activate the time check when the first command among them is input. For example, the memory controller 100 may perform a time check at a predetermined interval when the first command among the commands transmitted in succession from the host is input. Therefore, the time check points may have predetermined intervals therebetween.

Furthermore, the input command is stored in operation S40 in the command table memory 163 by the command data controller 133. Referring to FIGS. 6 and 7, the command table may include a timestamp regarding the point in time when the command was received by the host interface 110 and information regarding the type of the command (e.g., program command, read command, erase command, etc.). The command table may include timestamps S1, S2, S3, and S3 for a plurality of commands and information regarding the type of the command A, B, C, and D in a listed manner. For example, commands C and D may be different commands, but may be commands received at the same time S3. Referring to FIG. 7, the second time point S2 may be a time point after a predetermined time amount t1 has elapsed from the first time point S1, and the third time point S3 may be a time point after a predetermined time t2 has elapsed from the first time point S1.

The operation of activating the time check S50 and the subsequent operations will be described with reference to FIG. 8.

Referring to FIG. 8, as described above, the time check points may have predetermined intervals therebetween. For example, the multiple time check points may include a first time check point tp1, a second time check point tp2, a third time check point tp3, and a fourth time check point tp4. In FIG. 8, for convenience of description, the multiple time check points are illustrated as four, but the embodiments are not limited thereto. The predetermined interval tc between adjacent time check points among the time check points (tp1 to tp4) may be the same, but the embodiments of the present disclosure are not limited thereto, and the interval tc between the time check points (tp1 to tp4) may be changed as needed. The time checker 135 may be activated and perform time check when a command A is input.

Referring to FIGS. 8 and 9, the command complete controller 139 may receive the completion status of processing commands A to D from the memory 200 and inform the command data controller 133. As illustrated in FIG. 8, for example, when the process of commands A and B are completed before the first time check point tp1, the command complete controller 139 may receive a signal on the completion status of processing commands A and B from the memory 200 and inform the command data controller 133 of the completion status of processing commands A and B.

Next, referring to FIGS. 5 and 8, the operation method of the data processing system based on an embodiment includes a time checking operation S60. In FIG. 8, a first time check point tp1 may be initiated first. The time checking operation S60 may be repeatedly performed in the middle of the following operations, as shown in FIG. 8.

Next, referring to FIGS. 5 and 8, the method of operating the data processing system based on an embodiment includes an operation S70 of scanning a command table.

Referring to FIGS. 8 and 10, at the first time check point tp1, the time checker 135 may request the command data controller 133 to scan the command table, and the command data controller 133 may receive the command table from the command table memory 163 and scan the command table based on the request.

The command data controller 133 may scan the received command table. At this time, the received command table may only include information about process-uncompleted commands among the commands requested from the host. For example, as illustrated in FIG. 11, at the first time check point tp1, the scanned command table may include information about commands A and B, at the second time check point tp2, the scanned command table may include information about commands A and B, and at the third time check point tp3, the scanned command table may only include information about command A. The first and second time check points tp1 and tp2 may be points before the first threshold time points tsa and tsb, and the third time check point tp3 may be a point between the first threshold time points tsa and tsb and the second threshold time points tha and thb.

Next, referring to FIGS. 5 and 8, the method of operating the data processing system based on an embodiment includes an operation S80 of exceeding a first threshold time point. In this disclosure, the expression “(to) exceed a time point” means “(to) surpass a time point” or “(to) go beyond a time point”. For example, the operation S80 of exceeding a first threshold time point means a case where processing a command exceeds the first threshold time points tsa and tsb at a third time check point tp3. That is, it may be an operation of recognizing that processing a command has exceeded the first threshold time points tsa and tsb at a predetermined time check point as a result of the time check operation S60. Accordingly, since it is an operation that also includes a time check operation, the command table scanning operation S70 described above in FIG. 8 may also be performed simultaneously. Furthermore, a time checker (see 135 of FIG. 3) may determine whether processing a command has exceeded the first threshold time point at a predetermined time check point in time, and for example, the time checker 135 may determine whether processing a command has exceeded a first threshold time point at a predetermined time check point in time based on a first threshold time point based on a preset command reception point in time when a command is received from a host, but the embodiments are not limited thereto.

Based on an embodiment, the threshold time point may include a first threshold time point and a second threshold time point. The first threshold time point may be a time point earlier than the second threshold time point. In some embodiments, the first threshold time point may be a time point identical to the second threshold time point. In the embodiments below, the first threshold time point and the second threshold time point will be described with a focus on being distinguished. The first threshold time points tsa and tsb may be for commands A and B that are not process-completed at the third time check point tp3. For example, since command A is received before command B, the first threshold time point tsa of command A may be earlier than the first threshold time point tsb of command B. In FIG. 8, the period from the time each command is received to the first threshold time point is illustrated as being the same, but the embodiments are not limited thereto, and the first threshold time point may be different for each command. Hereinafter, the description will be made based on the case where the period from the time each command is received to the first threshold time point is the same. If the time check point in time surpasses the first threshold time point but does not surpass the second threshold time point, the memory system operation S10 may continue as illustrated in FIG. 5.

When, at the time check, the memory controller 100 completes the process of all the input commands A, B, C, and D, it may terminate the subsequent time check. In this case, the command table may be scanned first, and it may be determined that all the input commands A, B, C, and D are process-completed.

Next, referring to FIGS. 5, 8, and 12, after the operation of exceeding the first threshold time point S80, A first snapshot data generation operation S90 may be included. That is, since it is an operation that also includes the time check operation at the third time check point tp3, the command table scanning step S70 described above in FIG. 8 may also be performed simultaneously.

The time checker 135 may control the command table to be received by the command data controller 133 through the command data controller 133, and at the same time may request the snapshot data controller 137 to generate the first snapshot data, and the snapshot data controller 137 may generate the first snapshot data based on the request and store it in the snapshot data memory 165. In an embodiment, the first snapshot data may mean snapshot data generated when processing a command exceeds the first threshold time point at the time check point, and the second snapshot data to be described later may mean snapshot data generated when processing a command exceeds the second threshold time point. In an embodiment, snapshot data may mean data stored by creating an image that may represent the state of the entire memory system (see 10 of FIG. 1). That is, snapshot data may be a data image at a specific point in time (e.g., at the third time check point tp3 in the operation S90, rather than copy data that is a copy of data currently existing in the memory system 10.

Next, referring to FIGS. 5 and 8, the method of operating the data processing system based on an embodiment may include an operation S100 of exceeding a second threshold time point. For example, the operation S100 of exceeding the second threshold time point means a case where processing a command exceeds the second threshold time points tha and thb at a fourth time check point tp4. That is, it may be an operation of recognizing that processing a command has exceeded the second threshold time points tha and thb at a predetermined time check point as a result of the time check operation S60. Accordingly, since it is an operation that also includes the time check operation, the command table scanning operation S70 described above in FIG. 8 may also be performed simultaneously. Furthermore, the time checker (see 135 in FIG. 3) may determine whether processing a command has exceeded the second threshold time point at a given time check point, but the embodiments are not limited thereto.

In FIG. 8, at the fourth time check point tp4, the process of command B has already been completed, so only the second threshold time point tha of command A is shown.

Next, referring to FIGS. 5, 8 and 13, after the operation S100 of exceeding the second threshold time point, a second snapshot data generation operation S110 may be included. That is, at the fourth time check point tp4, the time checker 135 may control the command data controller 133 to receive a command table through the command data controller 133 and at the same time may request the snapshot data controller 137 to generate the second snapshot data, and the snapshot data controller 137 may generate the second snapshot data based on the request and store it in the snapshot data memory 165. In an embodiment, the second snapshot data may mean snapshot data generated when processing a command exceeds the second threshold time point at the time check point.

In an embodiment, the snapshot data may mean data stored by creating an image that can represent the state of the entire memory system (see 10 of FIG. 1). That is, the snapshot data may be a data image at a specific time point (for example, at the fourth time check point tp4 in operation S100, rather than copy data that is a copy of data currently existing in the memory system 10.

Next, referring to FIGS. 5 and 8, after the operation S100 of exceeding the second threshold time point, an operation S120 of entering a panic state may be included. In this disclosure, a panic state may mean a state in which a command specified in the specification of the Open Compute Project (OCP) cannot be processed. For example, in the panic state, the memory system 10 may be initialized or a recovery operation may be performed, but the embodiments are not limited thereto.

Hereinafter, the method of operating the data processing system based on an embodiment of the present disclosure will be described with a focus on the operation between the host and the memory system. A detailed description of the parts already described in FIGS. 5-13 will be omitted.

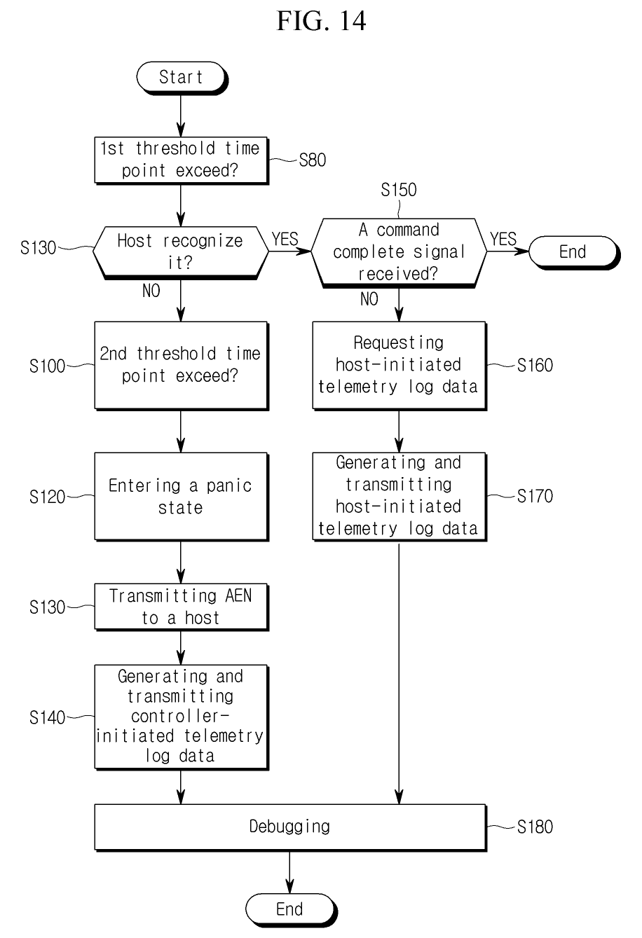

Referring to FIGS. 5, 8 and 14-17, the method of operating the data processing system based on an embodiment may include an operation S80 of exceeding a first threshold time point. The operation S80 of exceeding the first threshold time point is described above with reference to FIG. 5, so a repeated description thereof will be omitted.

Next, the method of operating the data processing system based on an embodiment may further include an operation S130 of determining whether the host has recognized, between the operation S80 of exceeding the first threshold time point and the operation S100 of exceeding the second threshold time point, whether processing a command requested by the memory system has exceeded the first threshold time point. That is, the operation S130 may mean a case where the host checks whether a process of the command has been completed on its own after requesting a command to the memory system.

In the above operation S80, when the host does not recognize whether processing the command requested to the memory system exceeds the first threshold time point (NO), then the operation S100 of exceeding the second threshold time point can be performed. The description of the operation S100 of exceeding the second threshold time point is omitted as it has been described above with reference to FIG. 5.

Next, the method of operating the data processing system based on an embodiment may include an operation S120 of entering a panic state. The operation S120 of entering a panic state is described above with reference to FIG. 5, so a repeated description will be omitted.

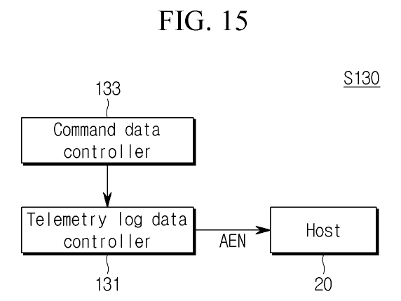

Next, the method of operating the data processing system based on an embodiment includes an operation S130 of transmitting an AEN (asynchronous request notifications) signal to the host. As illustrated in FIG. 15, in the operation S130 of transmitting an AEN signal to the host, the command data controller 133 may control the telemetry log data controller 131 to transmit an AEN signal to the host 20 when entering a panic state. In some embodiments, the command data controller 133 may not control the telemetry log data controller 131, but the command complete controller 139 may control the telemetry log data controller 131.

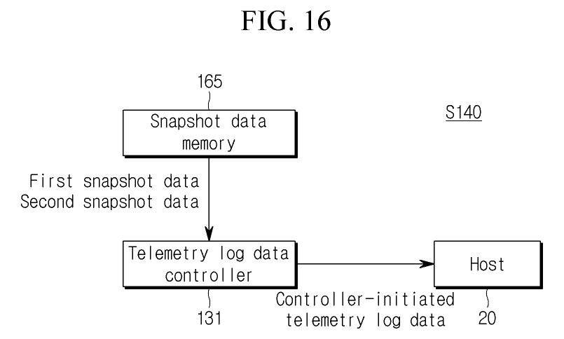

Next, the method of operating the data processing system based on an embodiment includes an operation S140 of generating and transmitting controller-initiated telemetry log data. As illustrated in FIG. 16, in the operation S140, the telemetry log data controller 131 may receive snapshot data (first snapshot data and second snapshot data) requested and stored in the snapshot data memory 165, generate controller-initiated telemetry log data including the snapshot data, and transmit the same to the host 20. In some embodiments, the telemetry log data controller 131 may control the snapshot data controller 137, so that the snapshot data controller 137 may receive snapshot data (first snapshot data and second snapshot data) requested and stored in the snapshot data memory 165, and transmit the same to the telemetry log data controller 131.

Meanwhile, in the operation S130, when the host is determined to have recognized, between the operations S80 and S100, whether the process of command requested by the host to the memory system has exceeded the first threshold time point (YES at operation S130), an operation S150 of determining whether a command completion signal has been received by the host may be included. In the operation S150, when the host receives the command completion signal from the command complete controller 139 that the process of command having exceeded the first threshold time point is completed (YES at operation S150), the host may not make any more requests. In the present disclosure, the first threshold time point may be referred to as a soft threshold time point, and the second threshold time point described below may be referred to as a hard threshold time point, but the embodiments are not limited thereto.

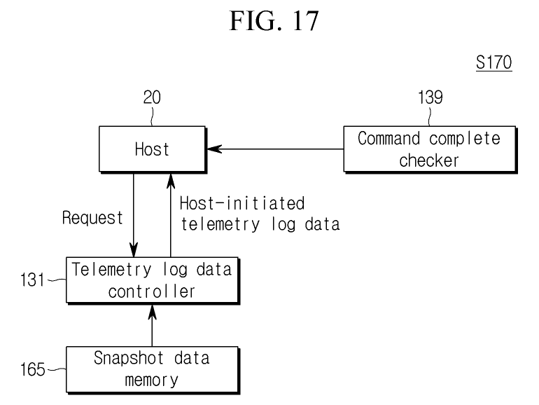

However, when the host does not receive a signal from the command complete controller 139 that the process of command having exceeded the first threshold time point is completed in the operation S150, a host-initiated telemetry log data request operation S160 is performed. As illustrated in FIG. 17, the host 20 may request the host-initiated telemetry log data controller 131.

Next, the method of operating the data processing system based on an embodiment includes an operation S170 of generating and transmitting host-initiated telemetry log data. As illustrated in FIG. 17, in the operation S170, the telemetry log data controller 131 may receive snapshot data (corresponding to the first snapshot data since processing a command has exceeded the first threshold time point, but in some cases, the first and second snapshot data when processing a command has exceeded the second threshold time point) requested and stored in the snapshot data memory 165, and may generate host-initiated telemetry log data including the snapshot data and transmit it to the host 20. In some embodiments, the telemetry log data controller 131 may control the snapshot data controller 137 so that the snapshot data controller 137 may receive the snapshot data requested and stored in the snapshot data memory 165 and transmit it to the telemetry log data controller 131. Telemetry log data transmitted via S140 and S170 may be used for debugging S180.

When the completion of processing a command requested by the host to the memory system is delayed (or the command timeout occurs) (e.g., processing a command exceeds the second threshold time point), it may be very important to identify the cause of this because it is directly related to the quality of service for the end user. When the completion of processing the command is delayed due to an internal problem of the memory system itself, since the memory system itself does not have a function to determine whether processing the command is completed, it performs a passive response based on the subsequent host action. For example, when the completion of processing the command is delayed, the host may apply a reset signal to the memory system, and then request the customer company to perform a defect analysis on the command timeout from the manufacturer.

However, at the point when the host recognizes that the completion of processing the command is delayed, there is a high possibility that data representing the state of the memory system is lost during the completion delay of processing the command.

Furthermore, when a command timeout is caused by a hard hang in the memory system, which the host does not recognize and cannot reset, it may lead to a Blue Screen of Death (BsoD), which may cause the entire memory system to go down.

However, based on the embodiments, the memory system detects by itself whether processing a command is completed and secures snapshot data on the internal state thereof before entering the operation or panic state thereof, the occurrence of reset hang and blue screen can be prevented, and in the future it is possible to analyze failure of the memory system using telemetry including snapshot data.

Although the embodiments of the present disclosure have been described with reference to the drawings, it is to be understood that the present invention is not limited to the embodiments and drawings disclosed in this specification, and those skilled in the art will appreciate that various modifications are possible without departing from the scope and spirit of the present disclosure. Further, although the operating effects based on the configuration of the embodiments are not explicitly described while describing the embodiments of the present disclosure, it should be appreciated that predictable advantageous effects are also to be recognized by the configuration. Furthermore, the embodiments may be combined to form additional embodiments.

### DESCRIPTION OF NUMERAL REFERENCES

10: Memory system

20: Host

100: Memory controller

200: Memory

What is claimed is:

1. A memory system comprising:
a memory comprising a plurality of memory blocks; and
a memory controller configured to:
perform a time check at a predetermined interval when a first command among commands transmitted from a host is input,
scan a command table of commands, processes of which are not completed among the commands, when a selected time point of the time check is before a first threshold time point,
scan the command table of commands, processes of which are not completed among the commands and generate first snapshot data, when the selected time point is between the first threshold time point and a second threshold time point, and
scan the command table of commands, processes of which are not completed among the commands, generate second snapshot data, and enter a state in which the command cannot be processed, when the selected time point is after the second threshold time point,
wherein the memory controller is further configured to transmit, to the host, telemetry log data including the first snapshot data or the second snapshot data.

2. The memory system of claim 1, wherein the memory controller is configured to terminate the time check when processing all of the input commands is completed at the selected time point.

3. The memory system of claim 1, wherein the first snapshot data and the second snapshot data are respective data images of the memory system at the selected time point.

4. The memory system of claim 1, wherein when the selected time point is between the first threshold time point and the second threshold time point, it is determined whether the host has recognized the presence or absence of process-uncompleted commands at the selected time point.

5. The memory system of claim 4, wherein the memory controller is configured to generate the second snapshot data when a next time point to the selected time point is beyond the second threshold time point when the host does not recognize the presence or absence of process-uncompleted commands at the selected time point.

6. The memory system of claim 5, wherein the memory controller is further configured to transmit an asynchronous request notifications (AEN) signal to the host after entering a state where the command cannot be processed.

7. The memory system of claim 5, wherein the telemetry log data is controller-initiated telemetry log data including the first snapshot data and the second snapshot data.

8. The memory system of claim 4, wherein the memory controller is configured to determine whether the host has received a command completion signal when the host has recognized the presence or absence of process-uncompleted commands at the selected time point.

9. The memory system of claim 8, wherein when the host does not receive the command completion signal, the host is configured to request host-initiated telemetry log data from the memory system.

10. The memory system of claim 9, wherein the telemetry log data is host-initiated telemetry log data including the first snapshot data.

11. The memory system of claim 1, wherein the command table is configured to store, for each of the commands transmitted from the host, information of a type of the command and a timestamp representing a time point that the memory system receives the command.

12. The memory system of claim 1, wherein the memory controller is configured to check whether processing the received command is completed, and the command table is updated based on whether processing the received command is completed.

13. A data processing system comprising:
a host; and
a memory system comprising a memory controller and a memory comprising a plurality of memory blocks,
wherein the memory controller is configured to generate, by itself, snapshot data representing an internal state of the memory system, and convert, by itself or in response to a request from the host, the snapshot data into telemetry log data and transmit the telemetry log data to the host.

14. A method of operating a data processing system comprising:
operating a memory system;
determining whether commands are input from a host;
performing a time check at predetermined intervals when a first command among commands transmitted from a host is input;
scanning, when a selected time point of the time check is before a first threshold time point, a command table of commands, processes of which are not completed among the commands;
generating, when the selected time point is between the first threshold time point and a second threshold time point, the command table of commands, process of which are not completed among the commands, and generating snapshot data;
scanning, when the selected time point is after the second threshold time point, the command table of commands, process of which are not completed among the commands, generating second snapshot data, and entering a state in which the command cannot be processed; and
transmitting, to the host, telemetry log data including the first snapshot data or the second snapshot data.

15. The method of operating the data processing system of claim 14, further comprising terminating performing the time check when processing all the input commands is completed at the selected time point.

16. The method of operating the data processing system of claim 14, wherein the first snapshot data and the second snapshot data are respective data images of the memory system at the selected time point.

17. The method of operating the data processing system of claim 14, wherein if the selected time point is between the first threshold time point and the second threshold time point, it is determined whether the host has recognized the presence or absence of process-uncompleted commands at the selected time point.

18. The method of operating the data processing system of claim 17, wherein the second snapshot data is generated when a next time point to the selected time point is beyond the second threshold time point when the host does not recognize the presence or absence of process-uncompleted commands at the selected time point.

19. The method of operating the data processing system of claim 18, further comprising transmitting an asynchronous request notifications (AEN) to the host after entering the state in which the command cannot be processed.

20. The method of operating the data processing system of claim 18, wherein the telemetry log data is controller-initiated telemetry log data including the first snapshot data and the second snapshot data.

21. The method of operating the data processing system of claim 17, further comprising determining whether the host has received a command completion signal when the host has recognized the presence or absence of process-uncompleted commands at the selected time point.

22. The method of operating the data processing system of claim 21, further comprising requesting, by the host, host-initiated telemetry log data from the memory system when the host does not receive the command completion signal.

23. The method of operating the data processing system of claim 22, wherein the telemetry log data is host-initiated telemetry log data including the first snapshot data.
